(19) United States
(12) Patent Application Publication
(10) Pub. No.: US 2012/0169577 A1
(43) Pub. Date: Jul. 5, 2012

(54) ARRAY SUBSTRATE AND METHOD FOR MANUFACTURING THE SAME

(75) Inventor: Rongge SUN, Beijing (CN)

(73) Assignees: Hefei Xinsheng Optoelectronics Technology Co., Ltd., Hefei City (CN); BOE TECHNOLOGY GROUP CO., LTD., Beijing (CN)

(21) Appl. No.: 13/332,575

(22) Filed: Dec. 21, 2011

(30) Foreign Application Priority Data
Dec. 29, 2010 (CN) 201010612945.0

(51) Int. Cl. G09G 3/36; H01L 33/58

(52) U.S. Cl. 345/92; 438/30; 257/E33.067

(57) ABSTRACT

The present disclosure provides an array substrate for a thin film transistor liquid crystal display (TFT-LCD), comprising: a base substrate having gate lines and data lines intersecting with each other to define sub-pixel units, each comprising a thin film transistor, a common electrode, a first pixel region and a second pixel region, wherein the first pixel region includes a first pixel electrode connected to the common electrode and a second pixel electrode connected to a drain electrode of the thin film transistor, and the first pixel electrode is on a same layer as and insulated from the second pixel electrode, and wherein the second pixel region includes a third pixel electrode connected to the common electrode and a fourth pixel electrode connected to the drain electrode, which are on a same layer and spaced apart from each other by a second local opening.

### BACKGROUND

Embodiments of the present disclosure relates to an array substrate of a thin film transistor-liquid crystal display (TFT-LCD) and a method for manufacturing the same.

Among liquid crystal displays of various types such as twisted nematic (TN), Vertical Alignment (VA) and plane field type LCD, the plane field type LCD becomes more and more popular due to advantages such as wide view angle, low chromatic aberration, high transmittance, and the like.

However, the plane field type TFT-LCD comprises an array substrate that is manufactured by a series of processes different from those for other types of liquid crystal displays. In an exemplary plain field type TFT-LCD, as shown in FIGS. 1 and 2, gate lines 1 and data lines 2 intersect to define pixel cells. In a manufacture process, layers (or elements) are formed in a following order: a first pixel electrode layer, which is typically formed of indium tin oxide (first ITO), comprising a first pixel electrode 8, as shown in FIG. 2; a gate metal layer comprising a pattern comprising gate lines 1, gate electrodes and common electrodes; a first insulating layer; a source/drain metal electrode layer comprising a source electrode 4 and a drain electrode 3 of a thin film transistor; a second insulating layer having drain contact holes 5; and a second pixel electrode layer (second ITO) comprising second pixel electrodes 6 and second pixel electrode layer openings 7. In the array substrate of the plane field type of TFT-LCD shown in FIG. 2, since two pixel electrode layers of ITO face each other, that is, overlap each other, resultant storage capacitance is large such that the pixel is charged slowly.

The inventors found that the array substrate of the plane field type of TFT-LCD provided as described above produces large storage capacitance, and the problem becomes more serious in products having a large size, a high resolution and multiplied frequency driving.

### SUMMARY

An aspect of the present disclosure provides an array substrate for a thin film transistor liquid crystal display (TFT-LCD), comprising: a base substrate having gate lines and data lines formed thereon and intersecting with each other to define sub-pixel units, each sub-pixel unit comprising a thin film transistor, a common electrode, a first pixel region and a second pixel region, wherein the first pixel region includes a first pixel electrode connected to the common electrode and a second pixel electrode connected to a drain electrode of the thin film transistor, the second pixel electrode comprises a first local opening, and the first pixel electrode is on a same layer as and insulated from the second pixel electrode, and wherein the second pixel region includes a third pixel electrode connected to the common electrode and a fourth pixel electrode connected to the drain electrode of the thin film transistor, and the third pixel electrode and the fourth pixel electrode are on a same layer and spaced apart from each other by a second local opening.

Another aspect of the present disclosure provides a method for manufacturing an array substrate for a thin film transistor liquid crystal display (TFT-LCD), comprising: forming a first pixel electrode layer film and patterning the first pixel electrode layer film to form a pattern comprising a first pixel electrode corresponding to a first pixel region in each sub-pixel unit, the first pixel electrode comprising a first local opening and connected with a common electrode; forming an insulating layer to cover the first pixel electrode layer; and forming a second pixel electrode layer film and patterning the second pixel electrode layer film to form a pattern comprising a second pixel electrode layer, comprising a second pixel electrode in the first pixel region of each sub-pixel unit and a third pixel electrode and a fourth pixel electrode in a second pixel region of each sub-pixel unit, wherein the second pixel electrode is connected to the fourth pixel electrode and connected through a drain contact hole to a drain electrode of a thin film transistor, the third pixel electrode is connected to the common electrode through a common electrode contact hole, and the third pixel electrode and the fourth pixel electrode are separated from each other by a second local opening.

Further scope of applicability of the present disclosure will become apparent from the detailed description given hereinafter. However, it should be understood that the detailed description and specific examples, while indicating preferred embodiments of the disclosure, are given by way of illustration only, since various changes and modifications within the spirit and scope of the disclosure will become apparent to those skilled in the art from the following detailed description.

### BRIEF DESCRIPTION OF THE DRAWINGS

The accompanying drawings, which are necessary for following description of embodiments of the present disclosure, will now be described briefly in order to fully disclose embodiments of the present disclosure or technical solutions in the related art. It is apparent that the accompanying drawings briefly described below show merely some embodiments of the present disclosure, and that those skilled in the art may obtain some other drawings on the basis of the accompanying drawings without any mental work.

FIG. 1 is a schematic view showing an array substrate of a plane field type of TFT-LCD in the related art;

FIG. 2 is a schematic sectional view taken along a line X-X′ in FIG. 1;

FIG. 3 is a schematic view showing an array substrate in a TFT-LCD in accordance with a first embodiment of the present disclosure;

FIG. 4 is a schematic sectional view taken along a line A-A′ in FIG. 3; and

FIG. 5 is a schematic view showing an array substrate in a TFT-LCD in accordance with a second embodiment of the present disclosure.

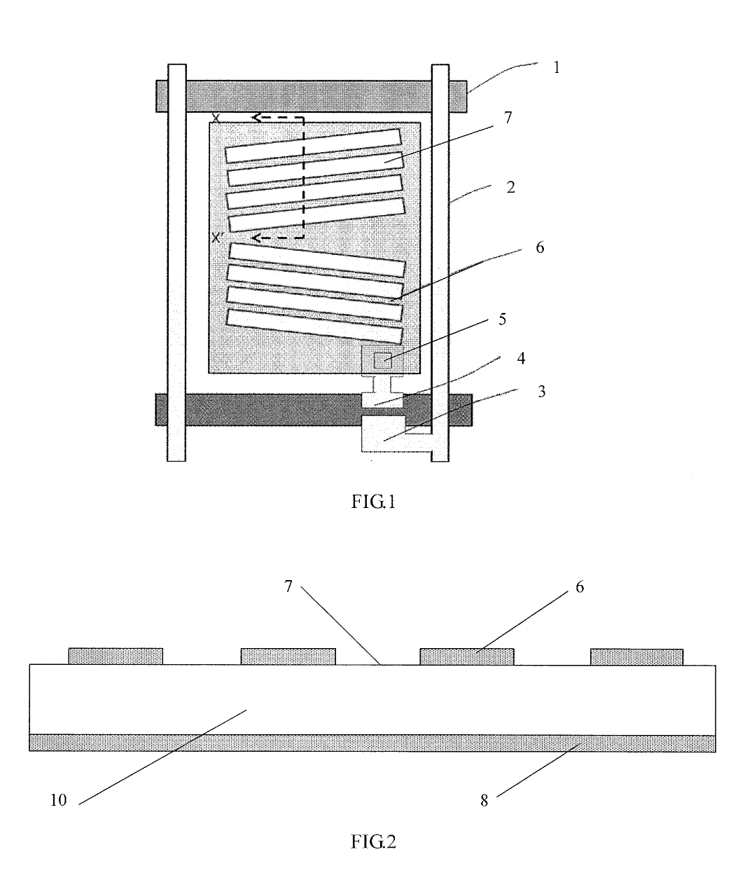

### DETAILED DESCRIPTION

Embodiments of the present disclosure will now be described more fully and clearly hereinafter with reference to the accompanying drawings in which the embodiments of the present disclosure are shown. It is to be recognized by those skilled in the art that the embodiments set forth herein are merely part rather than all of embodiments of the present disclosure. All other embodiments that can be obtained by those skilled in the art on the basis of the disclosed embodiments without any mental work may fall within the scope of the present disclosure.

An embodiment of the present disclosure provides an array substrate of a TFT-LCD capable of reducing storage capacitance and chromatic aberration and improving manufacturability, and also provides a method for manufacturing the same.

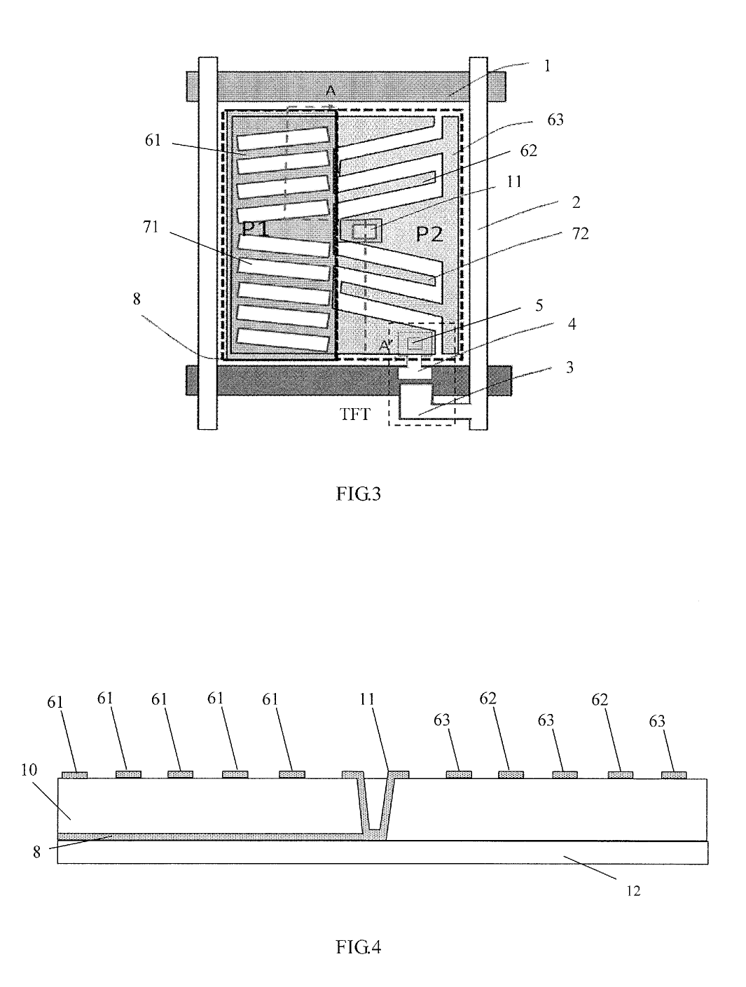

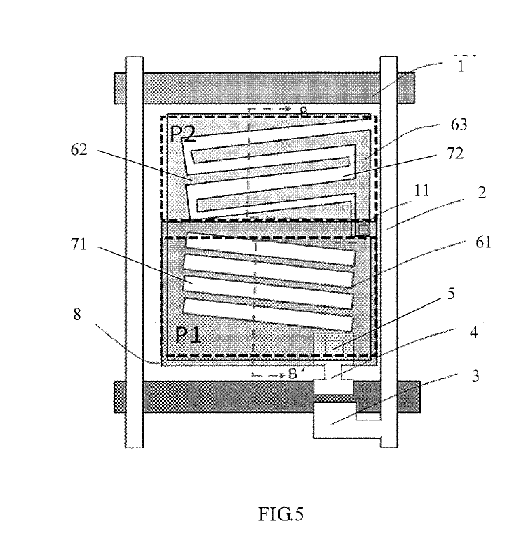

An embodiment of the present disclosure provide an array substrate of a TFT-LCD, as shown in FIGS. 3 and 4, comprising: a base substrate 12 (e.g., a glass substrate or plastic substrate); gate lines and data lines formed on the base substrate and intersecting so as to define sub-pixel units (or sub-pixel region), each of which comprises a thin film transistor, a common electrode a first pixel electrode layer and a second pixel electrode layer.

Each of the sub-pixel units comprises a first pixel region P1 and a second pixel region P2.

The first pixel region P1 may include the first pixel electrode layer 8 (example of a first pixel electrode) in connection with the common electrode and the second pixel electrode layer in connection with the drain electrode 4 of the thin film transistor. The second pixel electrode layer in the first pixel region P1 may have a pattern comprising a plurality of first region pixel electrodes 61 (example of a second pixel electrode) with first local openings 71 each interposed between and separating two adjacent first region pixel electrodes 61. The first pixel electrode layer 8 is separated from the second pixel electrode layer in the first pixel region P1 by an insulating layer 10.

The second pixel region P2 may include the second pixel electrode layer, and the second pixel electrode layer of the second pixel region P2 may have a pattern of a plurality of second region pixel electrodes comprising a second region first pixel electrode 62 (example of a fourth pixel electrode) and a second region second pixel electrode 63 (example of a third pixel electrode), and the electrodes 62 and 63 are spaced apart from each other. The second region first pixel electrode 62 is connected to the drain electrode 4 of the thin film transistor, and the second region second pixel electrode 63 is connected to the common electrode through the common electrode contact hole 11. The second region first pixel electrode 62 is separated from the second region second pixel electrode 63 by a second local opening 72.

The first region pixel electrode 61 may be in connection with the second region first pixel electrode 62 and be connected to the drain electrode 4 of the thin film transistor, for example, through a same drain contact hole 5, while the second region first pixel electrode 62 may be totally isolated from the second region second pixel electrode 63 without any contact therebetween.

In the array substrate in accordance with the present embodiment, the sub-pixel unit may be divided into two regions P1 and P2 by the pattern design of the first pixel electrode layer and the second pixel electrode layer. In the first pixel region P1, the plurality of first region pixel electrodes 61 of the second pixel electrode layer and the first pixel electrode layer 8 can form a plane field when applied a voltage across them, and in the second pixel region, the second region first pixel electrodes 62 and the second region second pixel electrodes 63 separated from each other may form another plane field when applied a voltage across them. Thus, when a voltage is applied to the source electrode, the field in the first pixel region P1 and the field in the second pixel region P2 have different effect, and when the pixel electrodes are applied with a same voltage, liquid crystal appears in different forms in the two regions, thereby improving chromatic aberration. In addition, since only one pixel electrode layer, i.e., the second pixel electrode layer, exists in the second pixel region P2, overlapping area between the first pixel electrode layer and the second pixel electrode layer can be reduced, thereby decreasing the storage capacitance.

Further, the second region first pixel electrode 62 and the second region second pixel electrode 63 can be completely separated from each other without any contact therebetween by the design of openings. The second local openings 72 each have a stripe shape, and two adjacent second local openings 72 are connected in series such that the second region pixel electrode is separated into the second region first pixel electrodes 62 in connection with the first region pixel electrodes 61 and the second region second pixel electrodes 63 in separation from the second region first pixel electrodes 62.

Further, a boundary between the first pixel region P1 and the second pixel region P2 may be in parallel with the gate line 1 of the sub-pixel unit, as shown in FIG. 5, or be in parallel with the data line 2 of the sub-pixel unit, as shown in FIG. 3. The embodiment shown in FIG. 5 works in the same in principle as the forgoing embodiment, and a detailed description thereof is omitted herein.

Further, in the two regions of each sub-pixel unit, the pixel electrodes may be provided in different angles. Specifically, assuming that the first region pixel electrode 61 has an angle of “a” with respect to the initial orientation of the liquid crystal, the second region pixel electrode has an angle of “b” that is different from “a” (i.e., a≠b) with respect to the initial orientation of the liquid crystal. By providing a different angle for the pixel electrodes in the two regions in each sub-pixel unit, the liquid crystal in each sub-pixel unit can have a large transmittance in both regions, and the chromatic aberration can be further improved.

The angle “a” of the first region pixel electrode 61 may be in a range of 5-15° with respect to the initial orientation of the liquid crystal, and the angle “b” of the second region pixel electrode may be in a range of 15-30° with respect to the initial orientation of the liquid crystal. In embodiments of the present disclosure, preferably, the angle “a” of the first region pixel electrode 61 may be in a range of 7-12° with respect to the initial orientation of the liquid crystal, and the angle “b” of the second region pixel electrode may be in a range of 15-20° with respect to the initial orientation of the liquid crystal.

In addition, the first pixel region P1 may have an area that is about 10%-90% of the total area of the sub-pixel unit.

In the embodiment of the present disclosure, each sub-pixel unit may be divided into two regions by the pattern design of the first pixel electrode layer and the second pixel electrode layer, and the two regions are driven by different type of plane fields, respectively, to display an image. Compared with the related art, the present disclosure can substantially decrease the storage capacitance of the pixel without any additional process, and thus it is more suitable for products having a large size, a high resolution and multiplied frequency driving. In addition, by improving the angle between the pixel electrode and the initial orientation of the liquid crystal in the two regions in the sub-pixel unit, the liquid crystal in each sub-pixel unit can appear in various forms, thereby reducing the chromatic aberration.

An embodiment of the present disclosure further provides a method for manufacturing the above-described array substrate of the TFT-LCD, and the method comprising the following steps.

Step 101, depositing a first pixel electrode layer film and patterning the first pixel electrode layer film to form a pattern comprising a first pixel electrode layer corresponding to a first pixel region in each sub-pixel unit;

Then, depositing a gate line metal layer film and patterning the gate line metal layer film to form a pattern comprising gate lines, gate electrodes and common electrodes, the first pixel electrode layer being connected to the common electrode; depositing a first insulating layer and a source/drain metal layer film sequentially and patterning the source/drain metal layer film to form a pattern comprising thin film transistors and data lines; depositing a second insulating layer and forming a drain contact hole corresponding to the drain of the thin film transistor and a common electrode contact hole corresponding to the common electrode in each sub-pixel unit by a patterning process. The first and second insulating layers can be collectively regarded as an insulating layer covering the first electrode layer.

It should be understood that sequence of the steps for forming the above patterns is merely for an illustration purpose, and the embodiments of the present disclosure are not limited thereto.

Step 102, depositing a second pixel electrode layer film and patterning the second pixel electrode layer film to form a second pixel electrode layer pattern comprising a plurality of first region pixel electrodes in a first pixel region of each sub-pixel unit and a plurality of second region pixel electrodes in a second pixel region of each sub-pixel unit, the second region pixel electrodes comprising a second region first pixel electrode and a second region second pixel electrode separated from each other, the second region first pixel electrodes being connected to the first region pixel electrodes and being connected to the drain of the thin film transistor through the drain contact hole, the second region second pixel electrodes being connected to the common electrode through the common electrode contact hole, the second region first pixel electrodes being spaced apart from the second region second pixel electrodes by second local openings.

In the present embodiment, the patterning process typically comprises steps of photoresist-coating, exposing, developing, etching, lift-off, and the like. The suitable photoresist comprises a positive type of photoresist or a negative type of photoresist.

In addition, the second local openings have a stripe shape, and every two adjacent second local openings are connected in series such that the second region pixel electrode may be divided into the second region first pixel electrodes connected to the first region pixel electrodes and the second region second pixel electrodes spaced apart from the second region first pixel electrodes.

Further, the boundary between the first pixel region and the second pixel region in each sub-pixel unit may be in parallel with the gate line or the data line.

Further, the first region pixel electrode forms an angle “a” with respect to the initial orientation of the liquid crystal, and the second region pixel electrode forms an angle “b,” which is different from a (i.e., a≠b), with respect to the initial orientation of the liquid crystal.

In the embodiments of the present disclosure, each sub-pixel unit may be divided into two regions by the pattern design of the first pixel electrode layer and the second pixel electrode layer, one region being driven by a fringe field, and the other being driven by a horizontal field, thereby displaying images. Compared with the related art, the present disclosure may substantially decrease the storage capacitance of the pixel without any additional process, and thus it is more suitable for products having large size, high resolution and multiplied frequency driving. In addition, by optimizing the angle between the pixel electrode and the initial orientation of the liquid crystal in the two regions in the sub-pixel unit, the liquid crystal may appear in various forms, thereby reducing the chromatic aberration.

While the present disclosure has been shown and described with regard to certain preferred embodiments, it is to be understood that modifications in form and detail will no doubt be developed by those skilled in the art upon reviewing this disclosure. It is therefore intended that the following claims cover all such alterations and modifications that nevertheless include the true spirit and scope of the inventive features of the present disclosure.

What is claimed is:

1. An array substrate for a thin film transistor liquid crystal display (TFT-LCD), comprising:
a base substrate having gate lines and data lines formed thereon and intersecting with each other to define sub-pixel units, each sub-pixel unit comprising a thin film transistor, a common electrode, a first pixel region and a second pixel region,
wherein the first pixel region includes a first pixel electrode connected to the common electrode and a second pixel electrode connected to a drain electrode of the thin film transistor, the second pixel electrode comprises a first local opening, and the first pixel electrode is on a same layer as and insulated from the second pixel electrode, and
wherein the second pixel region includes a third pixel electrode connected to the common electrode and a fourth pixel electrode connected to the drain electrode of the thin film transistor, and the third pixel electrode and the fourth pixel electrode are on a same layer and spaced apart from each other by a second local opening.

2. The array substrate of claim 1, comprising second local openings are in a stripe shape, wherein adjacent two second local openings are connected in series for spacing the third and fourth pixel electrodes.

3. The array substrate of claim 1, wherein a boundary between the first pixel region and the second pixel region is in parallel with the gate line or the data line.

4. The array substrate of claim 2, wherein a boundary between the first pixel region and the second pixel region is in parallel with the gate line or the data line.

5. The array substrate of claim 3, wherein the second pixel electrode forms is an angle “a” with respect to an initial orientation of liquid crystal, the third and fourth pixel electrodes form an angle “b” with respect to the initial orientation of the liquid crystal, and the angle “b” is different from the angle “a.”

6. The array substrate of claim 5, wherein the angle “a” is in a range of 5-15°, and the angle “b” is in a range of 15-30°.

7. The array substrate of claim 6, wherein the angle “a” is in a range of 7-12°, and the angle “b” is in a range of 15-20°.

8. The array substrate of claim 1, wherein the first pixel region has an area that is 10%-90% of a total area of each sub-pixel unit.

9. The array substrate of claim 1, wherein the second pixel electrode comprises a plurality of first local openings, and these first local openings are separated from each other.

10. The array substrate of claim 1, wherein in each sub-pixel unit the second, third and fourth pixel electrodes are provided on the same layer.

11. The array substrate of claim 10, wherein the second and fourth pixel electrodes are electrically connected with each other.

12. A method for manufacturing an array substrate for a thin film transistor liquid crystal display (TFT-LCD), comprising:
forming a first pixel electrode layer film and patterning the first pixel electrode layer film to form a pattern comprising a first pixel electrode corresponding to a first pixel region in each sub-pixel unit, the first pixel electrode comprising a first local opening and connected with a common electrode:
forming an insulating layer to cover the first pixel electrode layer; and
forming a second pixel electrode layer film and patterning the second pixel electrode layer film to form a pattern comprising a second pixel electrode layer, comprising a second pixel electrode in the first pixel region of each sub-pixel unit and a third pixel electrode and a fourth pixel electrode in a second pixel region of each sub-pixel unit, wherein the second pixel electrode is connected to the fourth pixel electrode and connected through a drain contact hole to a drain electrode of a thin film transistor, the third pixel electrode is connected to the common electrode through a common electrode contact hole, and the third pixel electrode and the fourth pixel electrode are separated from each other by a second local opening.

13. The method of claim 12, wherein second local openings are formed and in a stripe shape, and adjacent two second local openings are connected in series for spacing the third and fourth pixel electrodes.

14. The method of claim 13, wherein a boundary between the first pixel region and the second pixel region is in parallel with the gate line or the data line.

15. The method of claim 14, wherein the second pixel electrode forms an angle “a” with respect to an initial orientation of liquid crystal, the third and fourth pixel electrodes form an angle “b” with respect to the initial orientation of the liquid crystal, and the angle “b” is different from the angle “a.”
